(19) United States
(12) Patent Application Publication
(10) Pub. No.: US 2009/0075415 A1
(43) Pub. Date: Mar. 19, 2009

(54) Method for manufacturing semiconductor device

(75) Inventor: Makiko Nakamura, Tokyo (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 12/232,051

(22) Filed: Sep. 10, 2008

(30) Foreign Application Priority Data
Sep. 19, 2007 (JP) 2007-242356

(51) Int. Cl. H01L 21/00

(52) U.S. Cl. 438/51; 257/E21.001

(57) ABSTRACT

The present invention provides a method for manufacturing a semiconductor device which has an integrated circuit provided on a semiconductor substrate and a movable part which is movable relative to the substrate. This manufacturing method includes: a step of covering the movable part with a sacrificial film; a step of covering the sacrificial film with a first sealing layer which is formed of a material having a tensile stress; a step of forming a through-hole in the first sealing layer; a step of removing the sacrificial film through the through-hole to form a void around the movable part; and a step of film-forming a second sealing layer on the first sealing layer to close the through-hole.

### CROSS REFERENCE TO RELATED APPLICATION

This application claims the priority of Application No. 2007-242356, filed Sep. 19, 2007 in Japan, the subject matter of which is incorporated herein by reference.

### TECHNICAL FIELD OF THE INVENTION

The present invention relates to a method for manufacturing a semiconductor device using a micro electro mechanical system (MEMS) technique.

### BACKGROUND OF THE INVENTION

Recently, a device, in which a Micro Electro Mechanical System (hereinafter referred to as MEMS) formed of a machine structural part with a micron size and an electronic circuit are integrated on one substrate, as a high-value added device with a small size, a high function, and a high energy saving effect has attracted attention in many fields such as information and communications, medical care, biology, and vehicle. Regarding the device using the MEMS technique, in an MEMS resonator having an oscillator in its machine structural part, when a gas exists in the atmosphere, the operation is attenuated due to damping, and therefore, the surrounding of the oscillator is evacuated to be sealed. For instance, there is a method that a wafer used for a cover is laminated with a wafer with an oscillator formed thereon in a vacuum state to be sealed by using a bonding technology such as anodic bonding, direct bonding, eutectic bonding, and bonding using an adhesive. However, in this method, it is necessary to separately form the wafer used for a cover, and, in addition, it is necessary to provide a process of laminating the wafer used for a cover and the wafer with the oscillator formed thereon with each other with high accuracy, and therefore, there is a problem that the manufacturing cost is inevitably increased.

Therefore, there is proposed a sealing method of forming a sacrificial film around an oscillator formed on a substrate, forming a film as a cover on the sacrificial film to form a through-hole in the film as a cover, removing the sacrificial film through the through-hole, and, thus, to form a void part around the oscillator, and finally closing the through-hole by LPCVD (Low Pressure Chemical Vapor Deposition), whereby sealing is performed in a vacuum state comparable to an LPCVD atmosphere. (For example, U.S. Pat. No. 5,188,983).

However, in the above method, the through-hole is closed at a high temperature of about 550° C. or higher by LPCVD, and therefore, a structure formed before LPCVD is required to be formed to have high temperature resistance. Thus, a low melting point material such as aluminum cannot be used. Although it is preferable that the void part is sealed in a high vacuum state, it is difficult to achieve high vacuum in the sealing method using LPCVD. Further, as shown in FIG. 14 in U.S. Pat. No. 5,188,983, when sealing is performed by LPCVD, the sacrificial film is formed also around the oscillator located in the void part, and therefore, the characteristics of the oscillator may be varied.

### OBJECTS OF THE INVENTION

The present invention has been made in view of the above problems, and it is an object of the present invention to provide a method for manufacturing an MEMS device which can be stably operated with high accuracy.

Additional objects, advantages and novel features of the present invention will be set forth in part in the description that follows, and in part will become apparent to those skilled in the art upon examination of the following or may be learned by practice of the invention. The objects and advantages of the invention may be realized and attained by means of the instrumentalities and combinations particularly pointed out in the appended claims.

### SUMMARY OF THE INVENTION

A method for manufacturing a semiconductor device, which has an integrated circuit provided on a semiconductor substrate and a movable part which is movable relative to the substrate, includes a step of covering the movable part with a sacrificial film, a step of covering the sacrificial film with a first sealing layer which is formed of a material having a tensile stress, a step of forming a through-hole in the first sealing layer, a step of removing the sacrificial film through the through-hole to form a void around the movable part, and a step of film-forming a second sealing layer on the first sealing layer to close the through-hole.

According to the present invention, an MEMS device which can be stably operated with high accuracy for a long period of time can be manufactured.

### BRIEF DESCRIPTION OF THE DRAWINGS

FIG. 1 is a cross-sectional view of a semiconductor device according to a manufacturing method in a first embodiment of the present invention;

FIGS. 2A-2H are cress-sectional views showing the manufacturing method in the first embodiment of the present invention;

FIGS. 3A-3D are SEM photographs in which a cross-section of a device according to the manufacturing method in the first embodiment of the present invention is compared with a cross-section of a device according to the conventional manufacturing method;

FIG. 4 is a cross-sectional view of a semiconductor device according to a manufacturing method in a second embodiment of the present invention; and

FIGS. 5A-5H are cross-sectional views showing the manufacturing method in the second embodiment of the present invention.

### DETAILED DISCLOSURE OF THE INVENTION

In the following detailed description of the preferred embodiments, reference is made to the accompanying drawings which form a part hereof, and in which is shown by way of illustration specific preferred embodiments in which the inventions may be practiced. These preferred embodiments are described in sufficient detail to enable those skilled in the art to practice the invention, and it is to be understood that other preferred embodiments may be utilized and that logical, mechanical and electrical changes may be made without departing from the spirit and scope of the present inventions. The following detailed description is, therefore, not to be taken in a limiting sense, and scope of the present invention is defined only by the appended claims.

Hereinafter, an embodiment of a method for manufacturing an MEMS device according to the present invention is described with reference to the accompanying drawings.

### FIRST EMBODIMENT

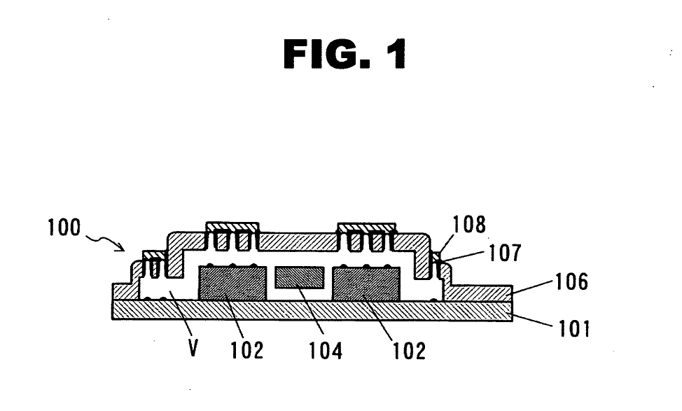

FIG. 1 shows a cross-sectional view of an MEMS resonator 100 manufactured by the manufacturing method according to a first embodiment in the present invention. The MEMS resonator 100 of the first embodiment includes a semiconductor substrate 101 having a transistor and a multilayer wiring (not shown), and electrodes 102 formed of an electroconductive material such as polysilicon and silicon-germanium is formed on the semiconductor substrate 101. Further, a movable part 104 such as an oscillator is formed on the semiconductor substrate 101 so as to separate from the main surface of the semiconductor substrate 101 and the electrodes 102. The movable part 104 is supported by a support part (not shown) in a cantilever manner or a fixed-fixed beam manner with respect to the semiconductor substrate 101. The thickness of the movable part 104 is about 1 to 5 μm. A sealing layer 106 formed of a sealing material such as silicon oxide film is further formed on the semiconductor substrate 101 so as to cover the electrodes 102 and the movable part 104. The sealing layer has through-holes formed in its predetermined position, and a first blocking film 107 and a second blocking film 108, formed of Ti and Al alloy, are formed so as to close the through-holes.

A void region V surrounded by the semiconductor substrate and the sealing layer 106 is maintained in high vacuum of about 0.9 m Torr, whereby attenuation in the operation of the movable part 104 caused by damping is prevented.

Next, a method for manufacturing the MEMS resonator 100 having the above constitution is described.

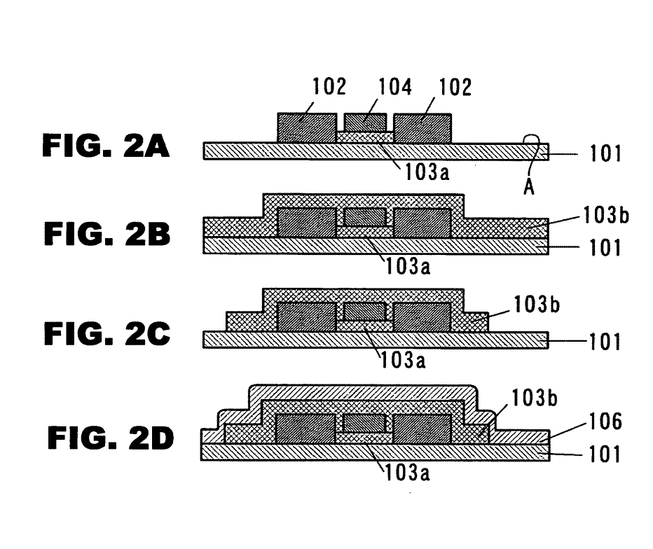

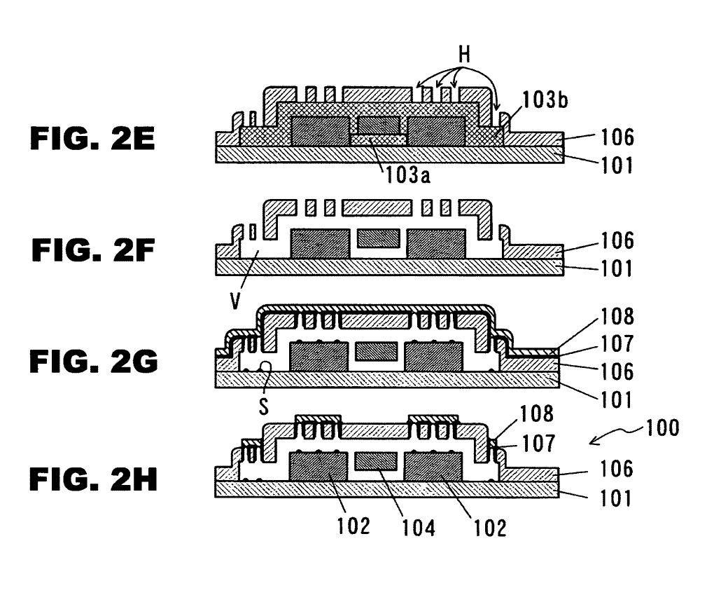

First, as shown in FIG. 2A, the electrodes 102 formed of an electroconductive material and the movable part 104 are formed on a main surface A of the semiconductor substrate 101 with a transistor and a multilayer wiring (not shown) are arranged thereon. The movable part 104 is separated from the electrodes 102 across a gap, and, at the same time, separated from the semiconductor substrate 101 through a sacrificial film 103a.

The electrode 102 and the movable part 104 can be formed by the following process, for example. First, the sacrificial film 103a of about 1 μm, formed of germanium or tungsten, is formed on the semiconductor substrate 101, formed of silicon or the like, by LP (Low Pressure)-CVD method, and the sacrificial film 103a is patterned into a predetermined pattern by a photolithographic etching technique. Next, an electroconductive material such as polysilicon is film-formed on the entire surface of a wafer. The electroconductive material is planarized by a planarization technique such as CMP (Chemical Mechanical Polishing), and thereafter, the electrodes 102 and the movable part 104 having a predetermined shape are formed by the photolithographic etching technique, whereby the structure shown in FIG. 2A is formed. Since the not shown transistor and multilayer wiring can be formed by a well-known technique such as CVD technique and photolithographic etching technique, the detailed description thereof is omitted.

Next, as shown in FIG. 2B, a sacrificial film 103b of about 1 μm, formed of germanium or tungsten, is formed on the structure shown in FIG. 2A by the LP-CVD method. At this time, the sacrificial film 103b is filled in the gap formed between the electrode 102 and the movable part 104.

Next, as shown in FIG. 2C, the sacrificial film 103b is patterned into a predetermined pattern by the photolithographic etching technique, whereby the sacrificial film 103b is formed only a region corresponding to a void region to be vacuum sealed, which will be described below.

Next, as shown in FIG. 2D, a sealing layer 106 of about 1.0 μm, formed of a material for sealing such as a silicon oxide film, is film-formed on the structure shown in FIG. 2C at a temperature of about 350 to 400° C. by an AP (Atmospheric Pressure)-CVD method using O₃ and TEOS (Tetraethylorthosilicate). According to this constitution, an outer shell defining a void region to be described below is formed.

Next, as shown in FIG. 2E, through-holes H with a diameter of about 0.3 to 0.5 μm are formed in the sealing layer 106 by the photolithographic etching technique. It is preferable that the through-hole H is not provided above the movable part 104 and above the vicinity of the movable part 104. Specifically, the through-hole H is prevented from being provided in a region located directly above the movable part 104 and the outer peripheral edge part having a width of about 2 μm. According to this constitution, the material for blocking is prevented from being deposited in the movable part 104 in the sputtering of the first blocking film 107 and the second blocking film 108 to be described below.

Next, as shown in FIG. 2F, the sacrificial films 103a and 103b are removed through the through-holes H. Specifically, the structure shown in FIG. 2E is immersed in a hydrogen peroxide solution, and the hydrogen peroxide solution is poured through the through-holes H to be brought into contact with the sacrificial films 103a and 103b, and, thus, to dissolve the sacrificial films 103a and 103b, whereby the dissolved sacrificial films 103a and 103b are removed through the through-holes H. According to this constitution, a void region V is formed around the movable part 104. Thereafter, the void region V is washed and dried in order to remove the hydrogen peroxide solution remaining therein.

Next, as shown in FIG. 2G, the first blocking film 107, which is formed of a blocking material such as titanium (Ti) with a film thickness of about 50 nm, is formed in the structure with the void region V formed therein by sputtering. Further, the second blocking film 108, which is formed of a blocking material such as aluminum (Al) alloy with a film thickness of about 1000 nm, is formed in the structure by sputtering.

Here, the second blocking film 108 is formed by passing through the following processes. In the initial stage of the film-formation process, the Al alloy is deposited mainly on the upper part of the through-hole H, and sediment having an overhang shape is formed on the upper part. When the film-formation of the Al alloy is further progressed, the overhang shape is gradually extended, and, thus, to gradually reduce the size of the opening formed above the through-hole H. When the film-formation of the Al alloy is further progressed, the opening above the through-hole H is blocked, the Al alloy, formed in the inner wall of the through-hole H so as to be extended in a thin film state, is pulled by the Al alloy sediment on the upper part of the through-hole H with its own surface tension, and, thus, to be moved up. According to this constitution, the upper part of the through-hole H is closed by the Al alloy having a substantially uniformed thickness.

Incidentally, it is desirable that the film-formation of the first blocking film 107 and the second blocking film 108 is continuously processed in a multichamber device in which feeding between chambers is performed while maintaining a vacuum state. In addition, the sputtering in the film-formation of the second blocking film 108 is desirably performed in an argon atmosphere of about 2 to 4 m Torr under a predetermined temperature condition. According to this constitution, when the second blocking film 108 is cooled until it reaches a room temperature after the film-formation, the void region can achieve a higher degree of vacuum than 2 to 4 m Torr which is the pressure upon sputtering of the Al alloy film. For example, when the sputtering of the Al alloy film is performed at the void region upon cooling until it reaches a room temperature is about 0.9 m Torr.

Finally, according to need, regarding the first blocking film 107 and the second blocking film 108, the film-formation part other than the part serving to close the through-hole H is removed by the photolithographic etching technique. According to this constitution, the MEMS resonator 100 shown in FIG. 2H is completed.

As above, when the MEMS device is manufactured by the manufacturing method in the first embodiment, the film-formation is performed by CVD at a relatively low temperature of about 350 to 400° C., and therefore, the structure formed before the CVD is not required to be formed to have high temperature resistance. In addition, the void region can be made in a high vacuum of about 0.9 m Torr, and thus, the operation is prevented from being attenuated by damping due to a gas existing in the atmosphere of the oscillator. Further, the through-hole is arranged at a proper position, and, thus, to prevent a sealing material from being deposited on the oscillator, whereby the oscillator with high accuracy can be formed.

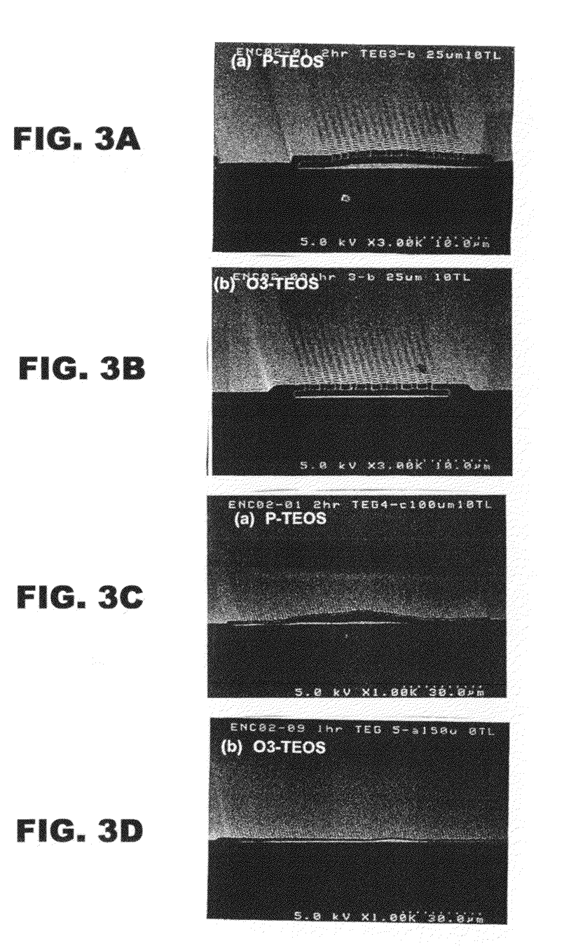

Furthermore, as above mentioned, when the sealing layer 106 is film-formed by the CVD method using O₃ and TEOS, even in a semiconductor device having a relatively large void region, the machine structural part can be formed with high accuracy. The film-formation of the sealing layer 106 is described hereinafter with reference to FIGS. 3A to D.

FIGS. 3A to 3D are SEM photographs in which a cross-section of a void region in the case in which a sealing layer is film-formed by the CVD method using O₃ and TEOS is compared with a cross-section of a void region in the case in which a silicon oxide film is formed by the CVD method using plasma TEOS, according to the first embodiment. FIG. 3A is an SEM photograph of the cross-section of the void region in the case in which an oxide film defining a void region with a width of 25 μm is formed by the conventional CVD method using plasma TEOS. FIG. 3B is an SEM photograph of the cross-section of the void region in the case in which the oxide film defining the void region with a width of 25 μm is formed by the CVD method using O₃ and TEOS in this embodiment. FIG. 3C is an SEM photograph of the cross-section of the void region in the case in which an oxide film defining a void region with a width of 100 μm is formed by the conventional CVD method using plasma TEOS. FIG. 3(d) is an SEM photograph of the cross-section of the void region in the case in which the oxide film defining the void region with a width of 100 μm is formed by the CVD method using O₃ and TEOS in this embodiment.

As seen in FIGS. 3A and 3B, in the void region with a relatively small width of about 25 μm, although the central part of the sealing layer is slightly curved in FIG. 3A using the plasma TEOS, the void region is formed without problems in both cases in FIGS. 3A and 3B. However, as seen in FIGS. 3C and 3D, in the void region with a relatively large width of about 100 μm, the central part of the sealing layer in FIG. 3C using the plasma TEOS is significantly curved in the state of being swollen up. Compared with this, the sealing layer in FIG. 3D using O₃ and TEOS is formed in a substantially planar shape.

Namely, when the sealing layer is formed by the CVD method using plasma TEOS, the compression stress of about 200 MPa is generated in the sealing layer, and therefore, it is considered that as soon as the sacrificial film supporting this compression stress is removed, the sealing layer is expanded to be deformed. Meanwhile, when the sealing layer is formed by the CVD method using O₃ and TEOS, it is possible to generate the tensile stress of about −100 MPa in the sealing layer. Thus, the sealing layer is not expanded to be deformed after the removal of the sacrificial film.

Even if the sealing layer is deformed to some extent, the sealing layer may be used without the operational problems in the MEMS device, but the shape of the sealing layer may be required to be controlled with high accuracy. In this case, in the manufacturing method in the first embodiment, even when the MEMS device which is formed of a machine structural part having a void region with a relatively large width is manufactured, the sealing layer can be formed with high accuracy.

### SECOND EMBODIMENT

Next, a manufacturing method according to a second embodiment of the present invention is described.

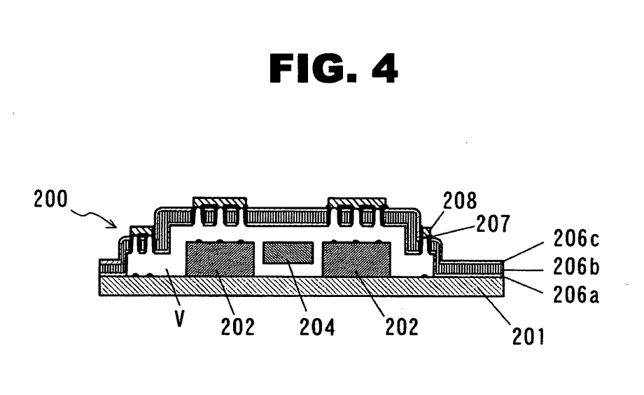

FIG. 4 shows a cross-sectional view of an MEMS resonator 200 manufactured by the manufacturing method according to the second embodiment of the present invention. Also in the MEMS resonator 200 in the second embodiment, as in the MEMS resonator 100 in the first embodiment, electrodes 202 and a movable part 204 are formed on a semiconductor substrate 201 having a transistor and a multilayer wiring (not shown), and these elements are covered by a sealing layer with through-holes formed therethrough, a first blocking film 207, and a second blocking film 208, these blocking films closing the through-holes and being formed of Ti and Al alloy. According to this constitution, the movable part 204 is sealed in a vacuum state. The MEMS resonator 200 in the second embodiment is characterized in that the electrodes 202 and the movable part 204 are sealed by sealing layers 206a, 206b, and 206c having a multilayer structure.

Namely, a sealing layer with a single layer formed by the AP-CVD method using O₃ and TEOS has a tensile stress, as described in the first embodiment, and therefore, the machine structural part can be formed with high accuracy without distorting the sealing layer; however, the sealing layer formed by the AP-CVD method using O₃ and TEOS has a rougher film quality than the sealing layer formed by the CVD method using plasma TEOS, and therefore, moisture is easily penetrated into the sealing layer. Accordingly, when the first blocking film and the second blocking film, which will be described below, are patterned, if the entire sealing layer is not further covered by a protective film such as a nitride film, the degree of vacuum may be gradually deteriorated.

Further, in the AP-CVD method using O₃ and TEOS used for the formation of a sealing layer, the ease of the occurrence of the film-formation depends on the state of the base, and therefore, the sealing layer may not be favorably film-formed depending on the kind of a material used in the sacrificial film to be described below. Further, a minute concavoconvex pattern may be formed on the surface of the sealing layer film-formed by the AP-CVD method using O₃ and TEOS, whereby the first blocking film and the second blocking film, which will be described below, may be film-formed with difficulty.

In order to avoid the above problems, the sealing layer in the second embodiment is characterized by being constituted of the sealing layer 206b formed by the AP-CVD method using O₃ and TEOS and the sealing layer 206a and/or 206c formed by the CVD method using plasma TEOS. Each sealing layer is film-formed to have a thickness so that the tensile stress is generated in the entirety of the sealing layers 206a, 206b, and 206c with a multilayer structure. Specifically, it is desirable that the sealing layers are film-formed so that the total thickness of the sealing layer 206a and the sealing layer 206c is not more than a half of the thickness of the sealing layer 206b.

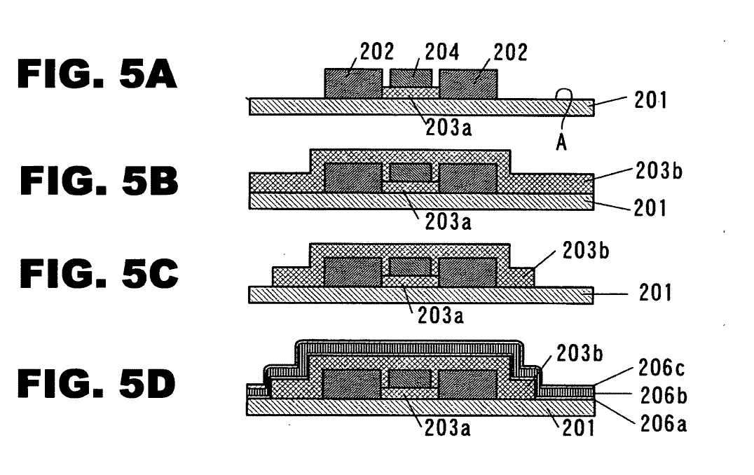

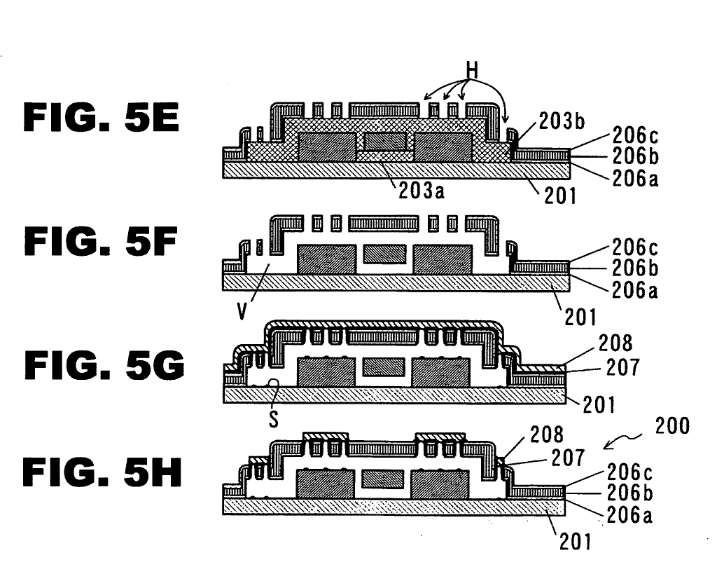

Next, a method for manufacturing the MEMS resonator 200 having the above constitution is described with reference to FIGS. 5A-5H.

First, as shown in FIG. 5A, the electrode 202 formed of an electroconductive material and the movable part 204 are formed on a main surface A of the semiconductor substrate 201 with a transistor and a multilayer wiring (not shown) are arranged thereon. The movable part 204 is separated from the electrodes 202 across a gap, and, at the same time, separated from the semiconductor substrate 201 through a sacrificial film 203a. The method of forming such a structure is substantially the same as in the first embodiment, and therefore, the description thereof is omitted.

Next, as shown in FIG. 5B, a sacrificial film 203b of about 1 μm, formed of germanium or tungsten, is formed on the structure shown in FIG. 5A by the LP-CVD method. At this time, the sacrificial film 203b is filled in the gap formed between the electrodes 202 and the movable part 204.

Next, as shown in FIG. 5C, the sacrificial film 203b is patterned into a predetermined pattern by the photolithographic etching technique. According to this constitution, the sacrificial film 203b is formed only in a region corresponding to a void region to be vacuum sealed, which will be described below.

Next, as shown in FIG. 5D, the first sealing layer 206a which is formed of a material for sealing such as a silicon oxide film and has a thickness of about 200 nm is film-formed on the structure shown in FIG. 5C by a plasma CVD method using TEOS or silane. Thereafter, the second sealing layer 206b which is formed of a material for sealing such as a silicon oxide film and has a thickness of about 1000 nm is film-formed by the AP-CVD method using O₃ and TEOS under a predetermined temperature condition. Further, the third sealing layer 206c which is formed of a material for sealing such as a silicon oxide film and has a thickness of about 200 nm is film-formed by the plasma CVD method using TEOS or silane. According to this constitution, an outer shell defining a void region to be described below is formed. In the above description, although the first sealing layer 206a and the third sealing layer 206c are respectively film-formed above and under the second sealing layer 206b, one of the first sealing layer 206a and the third sealing layer 206c may be film-formed so as to approach the second sealing layer 206b.

Next, as shown in FIG. 5E, through-holes H with a diameter of about 0.3 to 0.5 μm are formed in the sealing layers 206a, 206b, and 206c by the photolithographic etching technique. It is desirable that the through-hole H is not provided above the movable part 204 and above the vicinity of the movable part 204, as in the first embodiment.

Next, as shown in FIG. 5F, the sacrificial films 203a and 203b are removed by a method similar to the first embodiment. According to this constitution, a void region V is formed around the movable part 204. Thereafter, the void region V is washed and dried in order to remove the hydrogen peroxide solution remaining therein.

Next, as shown in FIG. 5G, a first blocking film 207, which is formed of a blocking material such as titanium (Ti) with a film thickness of about 50 nm, is formed in the structure with the void region V formed therein by sputtering. Further, a second blocking film 208, which is formed of a blocking material such as Al alloy with a film thickness of about 1000 nm, is formed in the structure by sputtering.

Incidentally, it is desirable that the film-formation of the first blocking film 207 and the second blocking film 208 are continuously processed in a multichamber device in which feeding between chambers is performed while maintaining a vacuum state. In addition, the sputtering in the film-formation of the second blocking film 208 is desirably performed in an argon atmosphere of about 2 to 4 m Torr under a predetermined temperature condition. According to this constitution, when the second blocking film 208 is cooled until it reaches a room temperature after the film-formation, the void region can achieve a higher degree of vacuum than 2 to 4 m Torr which is the pressure upon sputtering of the Al alloy film. For example, when the sputtering of the Al alloy film is performed at 400° C. in the argon atmosphere of 2 m Torr, the degree of vacuum in the void region upon cooling until it reaches a room temperature is about 0.9 m Torr.

Finally, according to need, the first blocking film 207 and the second blocking film 208 are partially removed by the photolithographic etching technique, with remaining necessary parts. According to this constitution, the MEMS resonator 200 shown in FIG. 5H is completed.

As above, when the MEMS device is manufactured by the manufacturing method in the second embodiment, in addition to the effects of the first embodiment, the following effects can be obtained. Specifically, the sealing layer defining the void region is formed of the layer which is formed by the CVD method using plasma TEOS and the layer which is formed by the AP-CVD method using O₃ and TEOS, and therefore, the film quality of the entire sealing layer becomes dense, whereby the high degree of vacuum can be maintained. Further, the sealing layer formed by the CVD method using plasma TEOS is stacked on the sacrificial film, and therefore, the ease of the occurrence of the film-formation of the sealing layer performed by using the CVD method using O₃ and TEOS is less likely to be affected by the material quality of the sacrificial film. Further, the sealing layer formed by the CVD method using plasma TEOS becomes a base for the first and second blocking films, whereby the film formation of the first and second blocking films is prevented from being unstable.

What is claimed is:

1. A method for manufacturing a semiconductor device, which has an integrated circuit provided on a semiconductor substrate and a movable part which is movable relative to the substrate, comprising:
covering the movable part with a sacrificial film;
covering the sacrificial film with a first sealing layer which is formed of a material having a tensile stress;
forming a through-hole in the first sealing layer;
removing the sacrificial film through the through-hole to form a void around the movable part; and
forming a second sealing layer on the first sealing layer to close the through-hole.

2. The method for manufacturing a semiconductor device according to claim 1, wherein
the semiconductor device is a micro electro mechanical system.

3. The method for manufacturing a semiconductor device according to claim 1, wherein
the first sealing layer is film-formed by an AP-CVD method using O₃ and TEOS.

4. The method for manufacturing a semiconductor device according to claim 1, wherein
the second sealing layer is film-formed by sputtering.

5. The method for manufacturing a semiconductor device according to claim 1, wherein
the second sealing layer is formed of aluminum.

6. The method for manufacturing a semiconductor device according to claim 1, wherein
the first sealing layer has a multilayer structure including at least two layers, and the multilayer structure includes a layer film-formed by the AP-CVD method using O₃ and TEOS and a layer film-formed by a plasma CVD method.

7. The method for manufacturing a semiconductor device according to claim 6, wherein
the multilayer structure has three layers, and a layer film-formed by the plasma CVD method, a layer film-formed by the AP-CVD method using O₃ and TEOS, and a layer film-formed by the plasma CVD method are sequentially stacked.

8. The method for manufacturing a semiconductor device according to claim 6, wherein
the total thickness of the layers film-formed by the plasma CVD method is not more than a half of the thickness of the layer film-formed by the AP-CVD method using O₃ and TEOS.

9. The method for manufacturing a semiconductor device according to claim 7, wherein
the total thickness of the layers film-formed by the plasma CVD method is not more than a half of the thickness of the layer film-formed by the AP-CVD method using O₃ and TEOS.
